(19) United States
(12) Patent Application Publication
(10) Pub. No.: US 2007/0232038 A1
(43) Pub. Date: Oct. 4, 2007

(54) Method of manufacturing plasma display panel and photomask to be used in the method

(76) Inventor: Hyo-Suk Lee, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/726,107

(22) Filed: Mar. 21, 2007

(30) Foreign Application Priority Data
Mar. 28, 2006 (KR) 10-2006-0028077

(51) Int. Cl. H01L 21/26; H01L 21/42

(52) U.S. Cl. 438/513

(57) ABSTRACT

Provided is a method of manufacturing a plasma display panel and a photomask to be used for manufacturing the plasma display panel. The method includes forming a conductive layer and a photoresist layer covering the conductive layer on a first substrate using a green sheet method, exposing and developing the photoresist layer to form a remaining photoresist layer that comprises a plurality of line pairs comprising a first line and a second line separated from each other and the first and second lines respectively comprise a plurality of stripe patterns extending in a direction and short bars that connect the stripe patterns wherein the widths of the stripe patterns and short bars near portions where the stripe patterns and short bars meet each other are formed smaller than the widths of the other portions of the stripe patterns and short bars, and forming a plurality of bus electrode pairs comprising a first bus electrode and a second bus electrode by etching portions of the conductive layer outside the remaining photoresist layer, wherein the first and second bus electrodes respectively comprise a plurality of strip shaped electrodes extending in a direction and short bars that connect the strip shaped electrodes.

### CROSS-REFERENCE TO RELATED PATENT APPLICATION

This application claims the benefit of Korean Patent Application No. 10-2006-0028077, filed on Mar. 28, 2006 in the Korean Intellectual Property Office, the disclosure of which is incorporated herein in its entirety by reference.

### BACKGROUND OF THE INVENTION

1. Field of the Invention

The present embodiments relate to a method of manufacturing a plasma display panel and a photomask to be used in the method, and more particularly, to a method of manufacturing a plasma display panel having enough opening ratio at a low cost and a photomask to be used in the method.

2. Description of the Related Art

Plasma display panels are flat display panels that display images using light emitted from a phosphor material excited by ultraviolet rays generated from gas discharge. Plasma display panels have received considerable attention as next generation thin and flat display devices due to their superior characteristics, such as large screen size with high image quality and ultra thin sizes. In order to increase luminance efficiency of the plasma display panel, the following conditions must be satisfied: the volume of a space in which sustain discharge for exciting a discharge gas is generated must be large, the surface area of a phosphor layer must be large, and elements that interrupt the progress of visible light emitted from the phosphor layer must be minimized.

FIG. 1 is a partially cutaway exploded perspective view illustrating a plasma display panel 100, and FIG. 2 is a cross-sectional view taken along a line II-II of FIG. 1. The plasma display panel (PDP) 100 includes a first substrate 111 and a second substrate 121 facing each other. Sustain electrode pairs 114 are disposed on a surface 111a of the first substrate 111 facing the second substrate 121, and a first dielectric layer 115 covering the sustain electrode pairs 114 and a passivation layer 116 covering the first dielectric layer 115 are formed on the first substrate 111. The sustain electrode pairs 114 include an X electrode 112 and a Y electrode 113, and each of the X and Y electrodes 112 and 113 includes transparent electrodes 112b and 113b and bus electrodes 112a and 113a. A plurality of address electrodes 122 parallel to each other are formed on a surface 121a of the second substrate 121 facing the first substrate 111. A second dielectric layer 123 covering the address electrodes 122, barrier ribs 124 formed on the second dielectric layer 123, and a phosphor layer 125 formed on a surface of the second dielectric layer 123 facing the first substrate 111 and on sidewalls of the barrier ribs 124 are formed on the second substrate 121.

In the case of the conventional PDP, the manufacturing cost is high. That is, the sustain electrode pairs 114 formed on the first substrate 111 include X and Y electrodes 112 and 113, and the X and Y electrodes 112 and 113 respectively includes transparent electrodes 112b and 113b and bus electrodes 112a and 113a, and the transparent electrodes 112b and 113b are mainly formed of a transparent material such as indium tin oxide (ITO). However, the material for forming a transparent electrode is expensive, thereby increasing manufacturing costs.

In order to solve this problem, as depicted in FIG. 3, a method of using a sustain electrode pair composed of only bus electrode pairs 104 without transparent electrodes has been proposed. That is, a first bus electrode 102 and a second bus electrode 103 of the bus electrode pair 104 are formed in a lattice shape to use a sustain electrode pair. More specifically, each of the first bus electrode 102 and the second bus electrode 103 is formed in a bus electrode pair having a lattice shape by including a plurality of stripe shaped electrodes 1021, 1022, 1023, 1031, 1032, and 1033 extending in a direction and short bars 1024 and 1034 that connect the stripe shaped electrodes 1021, 1022, 1023, 1031, 1032, and 1033 to each other. In this way, the PDP is manufactured with a lower cost without using the expensive transparent electrodes.

However, in the case of the conventional PDP, the rate of light extraction is low.

FIG. 4 is a photograph of a portion of the bus electrode pair of FIG. 3, and FIG. 5 is an enlarged view of the portion A in FIG. 4. Referring to FIGS. 4 and 5, in the case of the PDP having the sustain electrode pairs manufactured using the conventional method, the widths of the stripe shaped electrodes 1021, 1022, 1023, 1031, 1032, and 1033 and the short bars 1024 and 1034 where the stripe shaped electrodes 1021, 1022, 1023, 1031, 1032, and 1033 cross or meet the short bars 1024 and 1034 are increased. Therefore, there is a drawback in that the extraction of visible light generated from discharge cells is interrupted, thereby reducing the rate of light extraction.

### SUMMARY OF THE INVENTION

The present embodiments provide a photomask that ensures an opening ratio and a method of manufacturing a panel display panel with a low cost using the photomask.

According to an aspect of the present embodiments, there is provided a method of manufacturing a plasma display panel comprising forming a conductive layer and a photoresist layer covering the conductive layer on a first substrate using a green sheet method, exposing and developing the photoresist layer to form a remaining photoresist layer that comprises a plurality of line pairs comprising a first line and a second line separated from each other and the first and second lines respectively comprise a plurality of stripe patterns extending in a direction and short bars that connect the stripe patterns wherein the widths of the stripe patterns and short bars near portions where the stripe patterns and short bars meet each other are formed smaller than the widths of the other portions of the stripe patterns and short bars, and forming a plurality of bus electrode pairs comprising a first bus electrode and a second bus electrode by etching portions of the conductive layer outside the remaining photoresist layer, wherein the first and second bus electrodes respectively comprise a plurality of strip shaped electrodes extending in a direction and short bars that connect the strip shaped electrodes.

The photoresist layer may be a negative photoresist layer.

The photoresist layer may be a positive photoresist layer.

The method may further comprise combining the first substrate with a second substrate that comprises a plurality of address electrodes having a stripe shape, a plurality of barrier ribs that define discharge cells where a gas discharge is generated, and phosphor layers disposed in the discharge cells, wherein the first and second substrates are combined so that the bus electrode pairs can cross the address electrodes.

The method may further comprise forming a first dielectric layer that covers the bus electrode pairs.

The conductive layer may have a double layered structure.

The reflectance of an upper layer of the conductive layer may be greater than the reflectance of a lower layer of the conductive layer.

The light absorption rate of an upper layer of the conductive layer may be smaller than the light absorption rate of a lower layer of the conductive layer.

The exposing and developing of the photoresist layer may be performed using a photomask.

The exposing and developing of the photoresist layer may be performed using a direct image exposing method.

The forming of the conductive layer and the photoresist layer covering the conductive layer on the first substrate may be attaching a film having the conductive layer and the photoresist layer covering the conductive layer to the first substrate.

According to another aspect of the present embodiments, there is provided a method of manufacturing a plasma display panel comprising: forming a conductive layer and a photoresist layer that covers the conductive layer on a first substrate using a green sheet method; exposing and developing the photoresist layer to form a remaining photoresist layer that comprises a plurality of stripe patterns extending in a direction and short bars that connect the stripe patterns, wherein the widths of the stripe patterns and short bars near portions where the stripe patterns and short bars meet each other are formed smaller than the widths of the other portions of the stripe patterns and short bars; and forming electrodes by etching portions of the conductive layer exposed outside the remaining photoresist layer.

According to another aspect of the present embodiments, there is provided a photomask comprising: a transparent substrate; and a shielding unit that is disposed on the transparent electrode and comprises a plurality of opening unit pairs each having a first opening unit and a second opening unit, wherein the first and second opening units respectively comprise a plurality of stripe shaped first openings extending in a direction and second openings that connect the stripe shaped first openings, and the widths of the first opening and the second opening near portions where the first opening and the second opening meet are formed smaller than the widths of the other portions of the first opening and the second opening.

According to another aspect of the present embodiments, there is provided a photomask comprising: a transparent substrate; and a shielding unit that is disposed on the transparent electrode and comprises a plurality of shielding line pairs each having a first shielding line and a second shielding line, wherein the first and second shielding lines respectively comprise a plurality of stripe patterns extending in a direction and short bars that connect the stripe patterns, and the widths of the stripe patterns and short bars near portions where the stripe patterns and short bars meet are formed smaller than the widths of the other portions of the stripe patterns and short bars.

### BRIEF DESCRIPTION OF THE DRAWINGS

The above and other features and advantages of the present embodiments will become more apparent by describing in detail exemplary embodiments thereof with reference to the attached drawings in which:

FIG. 1 is a schematic partially cutaway exploded perspective view illustrating a conventional plasma display panel;

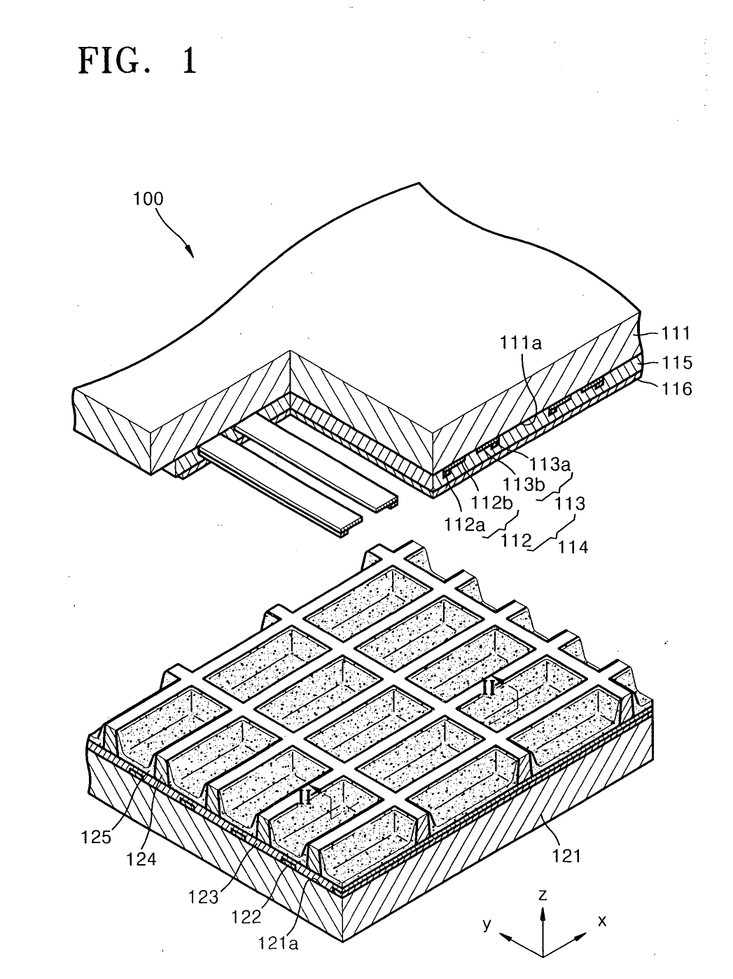

FIG. 2 is a cross-sectional view taken along a line II-II of FIG. 1;

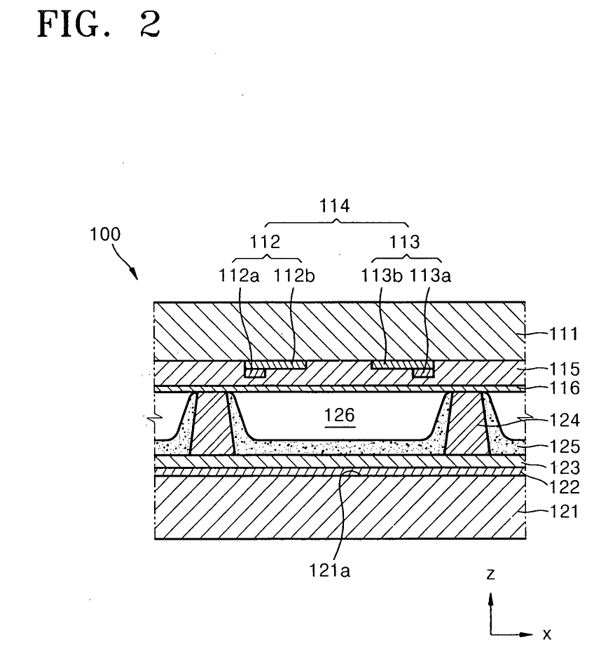

FIG. 3 is a schematic perspective view illustrating the structure of electrodes of a conventional plasma display panel;

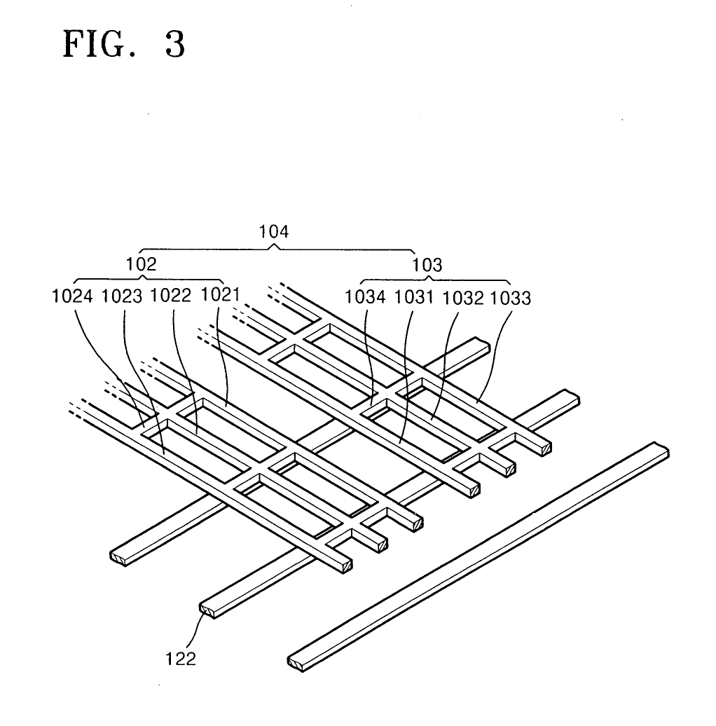

FIG. 4 is a photograph of a portion of the bus electrode pair of FIG. 3;

FIG. 5 is an enlarged view of the portion A in FIG. 4;

FIG. 6 is a schematic exploded perspective view illustrating a method of manufacturing a plasma display panel according to an embodiment;

FIGS. 7 through 9 are enlarged plan views of portion B in FIG. 6;

FIG. 10 is a schematic exploded perspective view illustrating a method of manufacturing a plasma display panel according to another embodiment; and

FIG. 11 is an enlarged view of the portion C in FIG. 10.

### DETAILED DESCRIPTION OF THE INVENTION

The present embodiments will now be described more fully with reference to the accompanying drawings in which exemplary embodiments are shown.

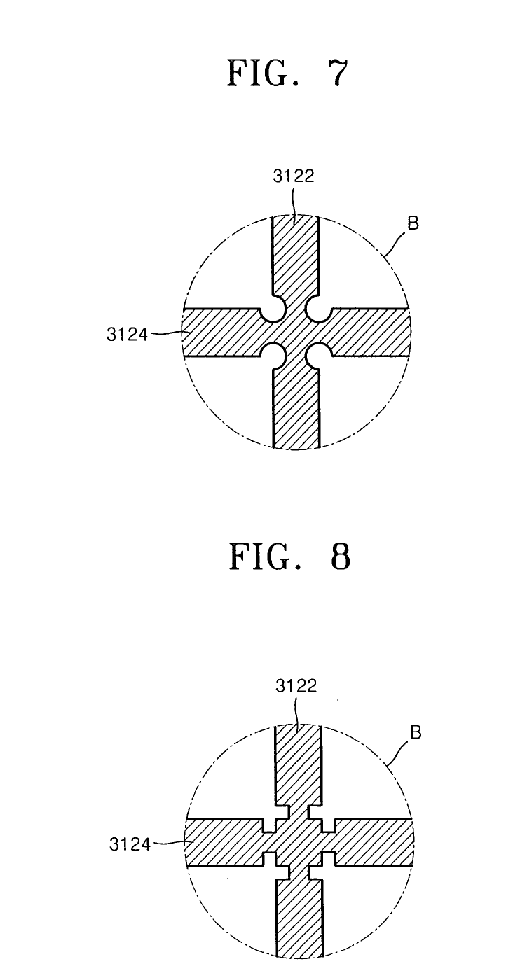

FIG. 6 is an exploded perspective view illustrating a method of manufacturing a plasma display panel (PDP) according to an embodiment.

A conductive layer 210a and a photoresist layer 210d covering the conductive layer 210a are formed on a first substrate 211. The conductive layer 210a can be a single layer or a multiple layer as necessary. Here, the conductive layer 210a can correspond to a bus electrode of a conventional PDP. In FIG. 6, the conductive layer 210a has a double layer structure.

An upper layer 210b of the conductive layer 210a can be formed to have higher reflectance than the reflectance of a lower layer 210c of the conductive layer 210a. That is, the upper layer 210b of the conductive layer 210a can be formed to have a smaller optical absorption rate than the optical absorption rate of the lower layer 210c of the conductive layer 210a. After the manufacturing of a PDP is complete, light generated in discharge cells is extracted to the outside through the first substrate 211 after passing between bus electrode pairs formed by patterning the conductive layer 210a. It is desirable that the surface material of the bus electrode pairs may have high reflectance, that is, low optical absorption rate. The blocking of external light incident to inner side of the PDP is also important. Therefore, the lower layer 210c of the conductive layer 210a is formed of a material having high optical absorption so that the external light incident to the inner side of the PDP through the first substrate 211 can be absorbed by the bus electrode pairs that are the first elements the external light meets.

The upper layer 210b of the conductive layer 210a can be formed of a mixture of Ag and a binder, and the lower layer 210c can be formed of a mixture of Ag, a binder, and a black pigment. The black pigment can be various materials such as Cr or Co. The materials for forming the conductive layer 210a are not limited thereto. Also, the structure of the conductive layer 210a is not limited thereto, that is, it can be formed to three or more layers. The lower layer 210c of the conductive layer 210a may not have conductivity.

Each layer of the multiple layer structure can be formed separately or in one process. In the latter case, the conductive layer 210a can be formed using a method, for example, in which after a conductive layer 210a having a multiple layer structure is formed on a film, the conductive layer 210a on the film can be transcribed to the first substrate 211. That is, the conductive layer 210a and the photoresist layer 210d covering the conductive layer 210a can be formed using a green sheet method. The green sheet method uses a green sheet that includes a base film, a conductive layer and a photoresist layer formed on the base film, and a cover film on the photoresist layer. After the conductive layer of the green sheet is tightly contacted on the first substrate 211 by removing the base film, the cover film is removed by laminating the resultant product. Thus, the conductive layer 210a and the photoresist layer 210d covering the conductive layer 210a are formed on the first substrate 211. When a conventional paste method is used, a paste is coated, dried, and burnt. However, in the green sheet method, the conductive layer 210a and the photoresist layer 210d are formed only through laminating and burning the layers, thereby reducing manufacturing process and time.

After the conductive layer 210a and the photoresist layer 210d covering the conductive layer 210a are formed as described above and depicted in FIG. 6, the conductive layer 210a is exposed and developed using a photomask 300. In FIG. 6, a positive photoresist layer in which the bonding of exposed portion of the photoresist layer 210d becomes weak is depicted.

The photomask 300 includes a transparent substrate 301 such as a glass substrate that transmits ultraviolet rays or a laser and a shielding unit formed of an optical shielding material such as Ni, Cr, or Co on the transparent substrate 301. The shielding unit includes shielding line pairs 314, and each of the shielding line pairs 314 includes a first shielding line 312 and a second shielding line 313 separated from each other. The first shielding line 312 includes a plurality of stripe patterns 3121, 3122, and 3123 extending in a direction and short bar patterns 3124 that connect the stripe patterns 3121, 3122, and 3123 to each other. The second shielding line 313 also includes a plurality of stripe patterns 3131, 3132, and 3133 extending in a direction and short bar patterns 3134 that connect the stripe patterns 3131, 3132, and 3133 to each other.

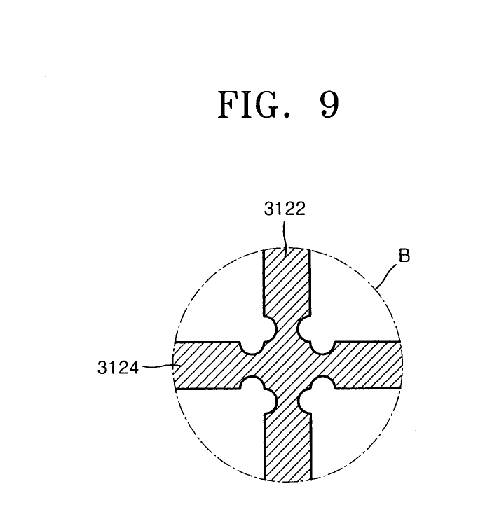

FIG. 7 is an enlarged plan view of the portion B in FIG. 6, that is, a crossing point between the stripe pattern 3122 and the short bar pattern 3124.

Referring to FIG. 7, the widths of the stripe pattern 3122 and the short bar pattern 3124 at the crossing point between the stripe pattern 3122 and the short bar pattern 3124 are formed smaller than the widths of other portions of the stripe pattern 3122 and the short bar pattern 3124.

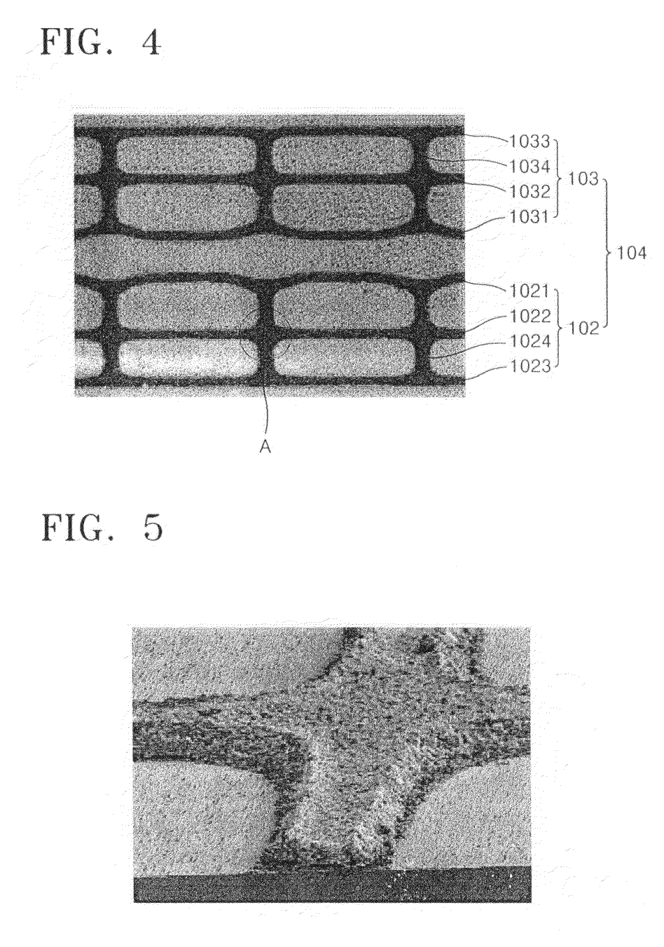

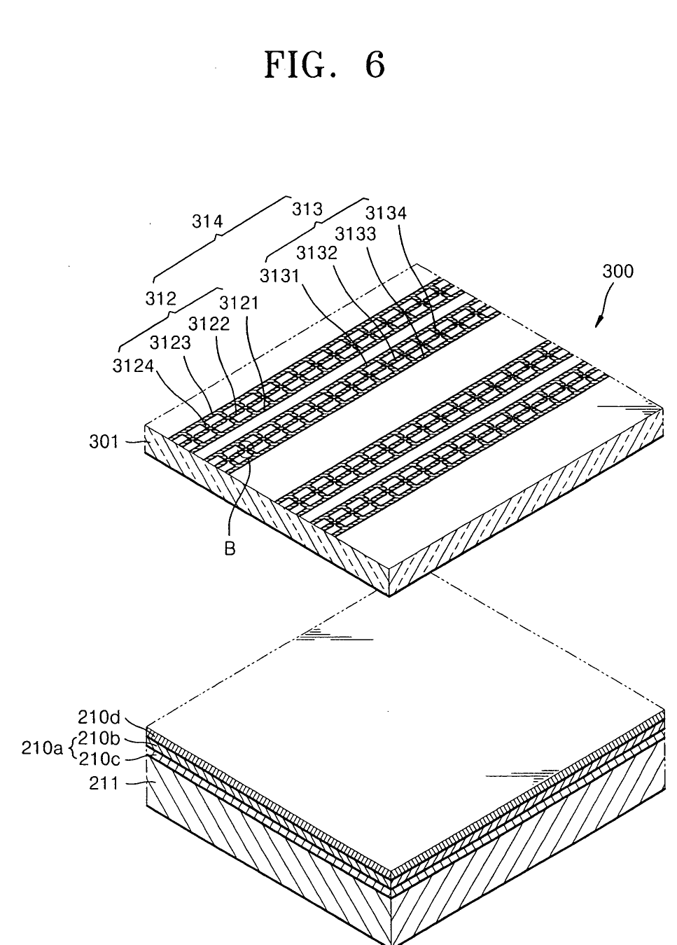

In the case of a photomask used for a conventional method of manufacturing an electrode, the patterns of a shielding unit of the photomask have the same widths without variations at the crossing points to each other. As a result, as depicted in FIGS. 4 and 5, the widths of the stripe pattern of the electrodes 1021, 1022, 1023, 1031, 1032, and 1033 and the short bars 1024 and 1034 are increased near portions where the stripe pattern of the electrodes 1021, 1022, 1023, 1031, 1032, and 1033 and the short bars 1024 and 1034 cross or meet. Thus, there is a drawback in that the extraction of visible light generated from discharge cells is interrupted, thereby reducing the rate of light extraction.

To solve the problem described above, as illustrated in FIGS. 6 and 7, the present embodiment uses the photomask 300 having a shielding unit in which the widths of the stripe patterns 3121, 3122, 3123, 3131, 3132, and 3133 and the short bar patterns 3124 and 3134 near portions where the stripe patterns 3121, 3122, 3123, 3131, 3132, and 3133 and the short bar patterns 3124 and 3134 cross or meet are formed smaller than the widths of other portions of the stripe patterns 3121, 3122, 3123, 3131, 3132, and 3133 and the short bar patterns 3124 and 3134.

The photoresist layer 210d which is a positive photoresist layer is exposed and developed using the photomask 300 described above. As a result, the remaining photoresist layer includes a plurality of line pairs having a first line and a second line separated from each other, and the first and second lines respectively include a plurality of stripe patterns and short bar patterns that connect the stripe patterns to each other, and the widths of the stripe patterns and the short bar patterns at portions near the stripe patterns and the short bar patterns cross or meet are formed smaller than the widths of the other portions of the stripe patterns and the short bar patterns.

A direct image exposing method can be used without using the photomask 300. That is, the photoresist layer can be exposed by irradiating light to the photoresist layer 210d, but the light is not irradiated to the entire region of the photoresist layer 210d but is irradiated to only portions of the region to be exposed. For example, the photoresist layer 210d is exposed using a laser beam, the laser beam is only radiated to portions to be exposed by moving a laser source that emits the laser beam.

Afterwards, a plurality of bus electrode pairs having first and second bus electrodes are formed by etching the portions of the conductive layer 210a exposed outside the remaining photoresist layer. The first and second bus electrodes respectively include a plurality of stripe shaped electrodes extending in a direction and short bars that connect the stripe shaped electrodes to each other. In the remaining photoresist layer pattern, the widths of the patterns near portions where the patterns cross or meet each other have smaller widths than other portions of the patterns. Therefore, unlike in the prior art, the widths of the stripe shaped electrodes and the short bars of each of the first and second bus electrodes near portions where the stripe shaped electrodes and the short bars cross or meet are not increased. As a result, light generated in discharge cells can be extracted to the outside without loss, thereby greatly increasing the optical absorption rate.

In the shielding unit of the photomask 300, the shape of the patterns that cross or meet is not limited to the shape shown in FIG. 7, but can have various shapes as depicted in FIGS. 8 and 9. That is, as long as the widths of the stripe pattern 3122 and the short bar pattern 3124 of the shielding unit of the photomask 300 near portions where the stripe pattern 3122 and the short bar pattern 3124 cross or meet are smaller than the widths of other portions of the stripe pattern 3122 and the short bar pattern 3124, it can be applied to the present embodiments.

After the bus electrode pairs are formed by patterning the conductive layer, the manufacture of a front panel having the first substrate 211 is completed by forming a first dielectric layer covering the bus electrode pairs. The first dielectric layer prevents the first and second bus electrodes of the bus electrode pairs from direct connection to each other and prevents the bus electrode pairs from being damaged by collision with charged particles. The first dielectric layer can be formed of, for example, PbO, B₂O₃, and SiO₂. In the case when light generated from discharge cells is extracted to the outside through the first substrate 211 after the manufacture of the PDP is complete, the first dielectric layer can be formed of a transparent material. A passivation film covering the first dielectric layer can further be formed as necessary.

After a second substrate that includes a plurality of address electrodes having a stripe shape, a plurality of barrier ribs that define a plurality of discharge cells where gas discharge generates, and phosphor layers formed in the discharge cells is manufactured, the manufacture of a PDP is completed by combining the second substrate with the first substrate 211. The first substrate 211 and the second substrate are combined so that the bus electrode pairs can cross the address electrodes.

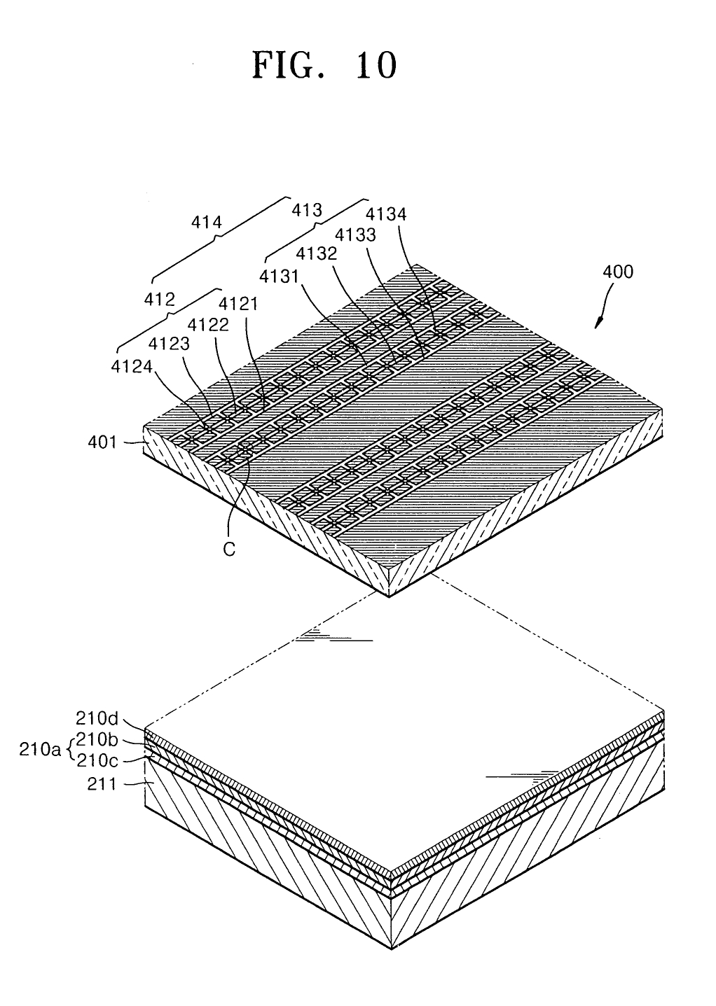

FIG. 10 is a schematic exploded perspective view illustrating a method of manufacturing a plasma display panel according to another embodiment.

In the previous embodiment, a positive photoresist layer is used as the photoresist layer. However, as depicted in FIG. 10, a negative photoresist layer can also be used as the photoresist layer.

After a conductive layer 210a and photoresist layer 210d covering the conductive layer 210a are formed on a first substrate 211, as depicted in FIG. 10, the photoresist layer 210d is exposed and developed using a photomask 400.

The photomask 400 includes a transparent substrate 401 such as a glass substrate that transmits ultraviolet rays or a laser and a shielding unit formed of an optical shielding material such as Ni, Cr, or Co on the transparent substrate 401.

The shielding unit includes a plurality of opening unit pairs 414, and each of the opening unit pairs 414 includes a first opening unit 412 and a second opening unit 413 separated from each other. The first opening unit 412 includes a plurality of stripe shaped first openings 4121, 4122, and 4123 extending in a direction and second openings 4124 that connect the stripe shaped first openings 4121, 4122, and 4123 to each other. The second opening unit 413 also includes a plurality of stripe shaped first openings 4131, 4132, and 4133 extending in a direction and second openings 4134 that connect the stripe shaped first openings 4131, 4132, and 4133 to each other.

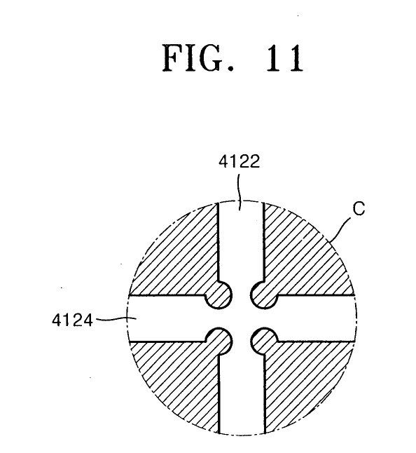

FIG. 11 is an enlarged view of the portion C of FIG. 10, that is, a crossing portion between the first opening 412 and the second opening 4124.

Referring to FIG. 11, the widths of the first opening 412 and the second opening 4124 near portions where the first opening 412 and the second opening 4124 meet are formed smaller than the widths of the other portions of the first opening 412 and the second opening 4124.

The photoresist layer 210d which is a positive photoresist layer is exposed and developed using the photomask 400 described above. As a result, the remaining photoresist layer includes a plurality of line pairs having a first line and a second line separated from each other, and the first and second lines respectively include a plurality of stripe patterns and short bar patterns that connect the stripe patterns to each other, and the widths of the stripe patterns and the short bar patterns near portions where the stripe patterns and the short bar patterns cross or meet are formed smaller than the widths of the other portions of the stripe patterns and the short bar patterns.

Afterwards, a plurality of bus electrode pairs having first and second bus electrodes are formed by etching the portions of the conductive layer 210a exposed outside the remaining photoresist layer. The first and second bus electrodes respectively include a plurality of stripe shaped electrodes extending in a direction and short bars that connect the stripe shaped electrodes to each other. In the remaining photoresist layer pattern, the widths of the patterns near portions where the patterns cross or meet each other have smaller widths than other portions of the patterns. Therefore, unlike in the prior art, the widths of the stripe shaped electrodes and the short bars of each of the first and second bus electrodes near portions where the stripe shaped electrodes and the short bars cross or meet are not increased. As a result, light generated in discharge cells can be extracted to the outside without loss, thereby greatly increasing the optical absorption rate.

In the shielding unit of the photomask 400, the shape of the openings that cross or meet is not limited to the shape shown in FIG. 11, but can have various shapes. That is, as long as the widths of the first openings 4121, 4122, 4123, 4131, 4132, and 4133 and the second openings 4124 and 4134 of the shielding unit of the photomask 400 near portions where the first openings 4121, 4122, 4123, 4131, 4132, and 4133 and the second openings 4124 and 4134 cross or meet are smaller than the widths of other portions of the first openings 4121, 4122, 4123, 4131, 4132, and 4133 and the second openings 4124 and 4134, it can be applied to the present embodiments.

A plasma display panel having greatly improved light extraction rate can be manufactured by manufacturing the plasma display panel using a photomask as described above when compared to a plasma display panel manufactured using a conventional photomask and a method of manufacturing the plasma display panel using the photomask.

A plasma display panel having greatly increased light extraction rate can be manufactured using a photomask and a method of manufacturing a plasma display panel according to the present embodiments.

While the present embodiments have been particularly shown and described with reference to exemplary embodiments thereof, it will be understood by those of ordinary skill in the art that various changes in form and details may be made therein without departing from the spirit and scope of the present embodiments as defined by the following claims.

What is claimed is:

1. A method of manufacturing a plasma display panel comprising:
forming a conductive layer and a photoresist layer covering the conductive layer on a first substrate using a green sheet method;
exposing and developing the photoresist layer to form a remaining photoresist layer that comprises a plurality of line pairs comprising a first line and a second line separated from each other;
wherein, the first and second lines respectively comprise a plurality of stripe patterns extending in a direction and short bars that connect the stripe patterns wherein the widths of the stripe patterns and short bars near portions where the stripe patterns and short bars meet each other are formed smaller than the widths of the other portions of the stripe patterns and short bars; and
forming a plurality of bus electrode pairs comprising a first bus electrode and a second bus electrode by etching portions of the conductive layer outside the remaining photoresist layer, wherein the first and second bus electrodes respectively comprise a plurality of strip shaped electrodes extending in a direction and short bars that connect the strip shaped electrodes.

2. The method of claim 1, wherein the photoresist layer is a negative photoresist layer.

3. The method of claim 1, wherein the photoresist layer is a positive photoresist layer.

4. The method of claim 1, further comprising combining the first substrate with a second substrate that comprises a plurality of address electrodes having a stripe shape, a plurality of barrier ribs that define discharge cells where a gas discharge is generated, and phosphor layers disposed in the discharge cells, wherein the first and second substrates are combined so that the bus electrode pairs can cross the address electrodes.

5. The method of claim 1, further comprising forming a first dielectric layer that covers the bus electrode pairs.

6. The method of claim 1, wherein the conductive layer has a double layered structure.

7. The method of claim 6, wherein the reflectance of an upper layer of the conductive layer is greater than the reflectance of a lower layer of the conductive layer.

8. The method of claim 6, wherein the light absorption rate of an upper layer of the conductive layer is smaller than the light absorption rate of a lower layer of the conductive layer.

9. The method of claim 1, wherein the exposing and developing of the photoresist layer is performed using a photomask.

10. The method of claim 1, wherein the exposing and developing of the photoresist layer is performed using a direct image exposing method.

11. The method of claim 1, wherein the forming of the conductive layer and the photoresist layer covering the conductive layer on the first substrate comprises attaching a film having the conductive layer and the photoresist layer covering the conductive layer to the first substrate.

12. A method of manufacturing a plasma display panel comprising:
forming a conductive layer and a photoresist layer that covers the conductive layer on a first substrate by using a green sheet method;
exposing and developing the photoresist layer to form a remaining photoresist layer that comprises a plurality of stripe patterns extending in a direction and short bars that connect the stripe patterns, wherein the widths of the stripe patterns and short bars near portions where the stripe patterns and short bars meet each other are formed smaller than the widths of the other portions of the stripe patterns and short bars; and
forming electrodes by etching portions of the conductive layer exposed outside the remaining photoresist layer.

13. A photomask comprising:
a transparent substrate; and
a shielding unit that is disposed on the transparent electrode and comprises a plurality of opening unit pairs each having a first opening unit and a second opening unit, wherein the first and second opening units respectively comprise a plurality of stripe shaped first openings extending in a direction and second openings that connect the stripe shaped first openings, and the widths of the first opening and the second opening near portions where the first opening and the second opening meet are formed smaller than the widths of the other portions of the first opening and the second opening.

14. A photomask comprising:
a transparent substrate; and
a shielding unit that is disposed on the transparent substrate and comprises a plurality of shielding line pairs each having a first shielding line and a second shielding line, wherein the first and second shielding lines respectively comprise a plurality of stripe patterns extending in a direction and short bars that connect the stripe patterns, wherein the widths of the stripe patterns and short bars near portions where the stripe patterns and short bars meet are formed smaller than the widths of the other portions of the stripe patterns and short bars.
